(19) United States
(12) Patent Application Publication
(10) Pub. No.: US 2026/0223462 A1
(43) Pub. Date: Jul. 30, 2026

(54) PROTECTION CIRCUIT AND SEMICONDUCTOR DEVICE INCLUDING THE PROTECTION CIRCUIT

(71) Applicant: ABLIC INC., Nagano (JP)

(72) Inventor: Tsutomu Tsutomu, Nagano (JP)

(21) Appl. No.: 19/455,378

(22) Filed: Jan. 21, 2026

(30) Foreign Application Priority Data
Jan. 28, 2025 (JP) 2025-011890
Sep. 24, 2025 (JP) 2025-158376

(51) Int. Cl. H10D 89/60; H02H 3/00; H10D 30/60; H10D 84/83; H10W 10/30

(52) U.S. Cl. CPC H10D 89/811; H02H 3/003; H10D 30/611; H10D 84/83125; H10W 10/30

(57) ABSTRACT

The protection circuit is formed on a semiconductor substrate including a substrate region of a first conductivity type, the substrate region containing a first conductivity type region and a second conductivity type region, and protects a protected circuit from applying a reverse polarity. The protected circuit includes a noise source, and is located between first and second power supply terminals and connected to the second power supply terminal via the protection circuit. The protection circuit includes a first protection transistor including a source and a back gate connected to a first circuit, a second protection transistor including a source and a back gate connected to a node connected to a second circuit while being isolated from the first circuit, and an isolation wall provided between the first and second protection transistors in a direction in which electrodes of the first and second protection transistors are arranged side by side.

### CROSS-REFERENCE TO RELATED APPLICATION

This application claims the priority benefits of Japanese patent applications no. 2025-11890 and no. 2025-158376 incorporated by reference herein and made a part of this specification.

### BACKGROUND

### 1. Field

The present invention relates to a protection circuit and a semiconductor device including the protection circuit.

### 2. Description of the Related Art

A power supply apparatus (for example, a secondary battery) for supplying electric power to a semiconductor device may apply a power supply voltage having a polarity reverse to a polarity applied in a steady state (hereinafter referred to simply as “reverse polarity”) due to reverse connection of a connector, noise, or the like. A general semiconductor device includes a parasitic diode forward-biased with respect to a reverse-polarity power supply voltage. For that reason, the application of the reverse-polarity power supply voltage to a semiconductor device without the application of the reverse-polarity power supply voltage taken into consideration causes an excessive forward current to flow through the parasitic diode, and may cause damage to an element forming the semiconductor device. The technology for protecting an integrated circuit is disclosed from the viewpoint of preventing such damage to an element caused by the application of the reverse-polarity power supply voltage as described above (see, for example, Japanese Patent Application Laid-open No. Hei 10-289956).

A protection circuit to which the technology as disclosed in Japanese Patent Application Laid-open No. Hei 10-289956 is applied includes an NPN bipolar transistor. The NPN bipolar transistor includes: a base connected to a VCC terminal for supplying a power supply voltage VCC (≠0 V) through a resistor; a collector connected to an internal circuit to be protected (hereinafter referred to as one of “protection target” or “protected circuit”); and an emitter connected to a GND terminal for supplying a power supply voltage of 0 V.

In a state in which the reverse-polarity power supply voltage is not applied, that is, in a steady state in which the power supply voltage VCC is a positive voltage (VCC>0), the power supply voltage VCC sufficiently higher than a forward voltage Vf of a base-emitter diode of the NPN bipolar transistor increases a current driving capability, and a collector-emitter voltage can be regarded as substantially 0 V. Thus, in the steady state, the internal circuit can be regarded as being directly connected to the GND terminal.

Meanwhile, in a state in which the reverse-polarity power supply voltage is applied, that is, in a reverse connection state of a power supply in which the power supply voltage VCC is a negative voltage (VCC<0), a base voltage follows the power supply voltage VCC, thereby preventing a base current from flowing. Thus, the NPN bipolar transistor included in the protection circuit is brought into a cutoff state, thereby blocking a collector current. Through the blocking of the collector current, it is possible to block an excessive forward current to be caused to flow through the parasitic diode to cause damage to an element at a time of having the internal circuit directly connected to the GND terminal. As a result, the protection target can be protected from damage to the element caused by the application of the reverse-polarity power supply voltage.

However, the protection circuit and the semiconductor device including the protection circuit according to the related art, such as those disclosed in Japanese Patent Application Laid-open No. Hei 10-289956, may adversely affect a protection target depending on the configuration of a circuit serving as the protection target, thereby providing room for improvement. For example, in a case in which the circuit serving as the protection target is a mixed internal circuit including an analog circuit handling a DC voltage or a continuous signal, and a digital circuit handling discrete signals and also controlling a switching power supply or a charge pump allowing a large current to flow in accordance with a switching operation, a fluctuation occurs in the collector voltage in the steady state due to a current flowing from the digital circuit or a DC-DC converter to the NPN bipolar transistor. Such a fluctuation in the collector voltage appears as noise in the analog circuit, thereby adversely affecting signal processing in the analog circuit.

In order to reduce noise in the analog circuit, the NPN bipolar transistor included in the protection circuit can be changed to an NPN bipolar transistor having a higher current driving capability. However, the area of the bipolar transistor tends to increase as the current driving capability increases. Accordingly, the adoption of the NPN bipolar transistor having a higher current driving capability increases the area of the protection circuit, thereby in turn leading to higher cost.

The present invention has an object to provide a protection circuit capable of protecting a protection target from application of a reverse-polarity power supply voltage while suppressing an increase in cost and an adverse effect on the protection target, and a semiconductor device including the protection circuit.

### SUMMARY

A protection circuit according to at least one embodiment of the present invention is formed on a semiconductor substrate including a substrate region of a first conductivity type, a region of the first conductivity type formed in the substrate region, and a region of a second conductivity type formed in the substrate region. The protection circuit is configured to protect a protected circuit from application of a power supply voltage having a reverse polarity to a polarity of a power supply voltage applied in a steady state. The protected circuit includes a first circuit located between a first power supply terminal and a second power supply terminal and connected to the second power supply terminal via the protection circuit, the first circuit including a noise source. The protected circuit further includes a second circuit located between the first power supply terminal and the second power supply terminal and connected in parallel to the first circuit via the protection circuit. The protection circuit includes a first protection transistor including a drain connected to the second power supply terminal, a gate configured to receive supply of a first control voltage, and a source and a back gate connected to the first circuit. The protection circuit further includes a second protection transistor including a drain connected to the drain of the first protection transistor, a gate configured to receive supply of a second control voltage, and a source and a back gate which are electrically isolated from a connection point of the source and the back gate of the first protection transistor and the first circuit and connected to the second circuit. The drain, the gate, the source, and the back gate of the second protection transistor position side by side in a first direction along a surface of the semiconductor substrate in which the drain, the gate, the source, and the back gate of the first protection transistor arrange side by side. The protection circuit further includes an isolation wall provided between the first protection transistor and the second protection transistor in the first direction. The isolation wall is floating.

A protection circuit according to at least one embodiment of the present invention is formed on a semiconductor substrate including a substrate region of a first conductivity type, a region of the first conductivity type formed in the substrate region, and a region of a second conductivity type formed in the substrate region. The protection circuit is configured to protect a protected circuit from application of a power supply voltage having a reverse polarity to a polarity of a power supply voltage applied in a steady state. The protected circuit includes a first circuit located between a first power supply terminal and a second power supply terminal and connected to the second power supply terminal via the protection circuit, the first circuit including a noise source. The protected circuit further includes a second circuit located between the first power supply terminal and the second power supply terminal and connected in parallel to the first circuit via the protection circuit. The protection circuit includes a first protection transistor including a drain connected to the second power supply terminal, a gate configured to receive supply of a first control voltage, and a source and a back gate connected to the first circuit. The protection circuit further includes a second protection transistor including a drain connected to the drain of the first protection transistor, a gate configured to receive supply of a second control voltage, and a source and a back gate which are electrically isolated from a connection point of the source and the back gate of the first protection transistor and the first circuit and connected to the second circuit. The drain, the gate, the source, and the back gate of the second protection transistor position side by side in a first direction along a surface of the semiconductor substrate in which the drain, the gate, the source, and the back gate of the first protection transistor arrange side by side. The protection circuit further includes an isolation wall of the second conductivity type provided between the first protection transistor and the second protection transistor in the first direction. A voltage equal to or higher than a voltage of the substrate region is to be applied to the isolation wall.

A semiconductor device according to at least one embodiment of the present invention includes a semiconductor integrated circuit formed on a semiconductor substrate including a substrate region of a first conductivity type, a region of the first conductivity type formed in the substrate region, and a region of a second conductivity type formed in the substrate region. The semiconductor integrated circuit includes the protection circuit described above. The protected circuit includes a first circuit located between a first power supply terminal and a second power supply terminal and connected to the second power supply terminal via the protection circuit, the first circuit including a noise source. The protected circuit further includes a second circuit located between the first power supply terminal and the second power supply terminal and connected in parallel to the first circuit via the protection circuit.

According to the protection circuit and the semiconductor device, a protection target can be protected from the application of the reverse-polarity power supply voltage, while an increase in cost and an adverse effect on the protection target are suppressed.

### BRIEF DESCRIPTION OF THE DRAWINGS

FIG. 1 is a circuit diagram of a semiconductor device including a protection circuit according to at least one embodiment of the present invention.

FIG. 2A is a circuit diagram for illustrating a current source serving as a first configuration example of a load of a step-down circuit in the semiconductor device according to the at least one embodiment.

FIG. 2B is a circuit diagram for illustrating a first configuration example of the current source serving as the first configuration example of the load of the step-down circuit in the semiconductor device according to the at least one embodiment.

FIG. 2C is a circuit diagram for illustrating a second configuration example of the current source serving as the first configuration example of the load of the step-down circuit in the semiconductor device according to the at least one embodiment.

FIG. 3 is a cross-sectional view of a protection circuit (a first configuration example) included in the semiconductor device according to the at least one embodiment.

FIG. 4 is a cross-sectional view of a protection circuit (a second configuration example) included in the semiconductor device according to the at least one embodiment.

FIG. 5 is a cross-sectional view of a protection circuit (a third configuration example) included in the semiconductor device according to the at least one embodiment.

FIG. 6A is a circuit diagram for illustrating a second configuration example of a load in the semiconductor device according to the at least one embodiment.

FIG. 6B is a circuit diagram for illustrating a third configuration example of a load in the semiconductor device according to the at least one embodiment.

FIG. 6C is a circuit diagram for illustrating a fourth configuration example of a load in the semiconductor device according to the at least one embodiment.

FIG. 7A is a circuit diagram for illustrating a second configuration example of the step-down circuit in the semiconductor device according to the at least one embodiment.

FIG. 7B is a partial circuit diagram of a third configuration example of the step-down circuit in the semiconductor device according to the at least one embodiment.

FIG. 8A is a circuit diagram for illustrating a first configuration example of a current source serving as the second configuration example of the step-down circuit in the semiconductor device according to the at least one embodiment.

FIG. 8B is a circuit diagram for illustrating a second configuration example of the current source serving as the second configuration example of the step-down circuit in the semiconductor device according to the at least one embodiment.

FIG. 9 is a circuit diagram for illustrating a fourth configuration example of the protection circuit and the semiconductor device according to the at least one embodiment.

### DESCRIPTION OF THE EMBODIMENTS

Now, a protection circuit and a semiconductor device including the protection circuit according to at least one embodiment of the present invention are described with reference to the attached drawings by taking a mixed circuit including a circuit including a noise source and a circuit that may be affected by noise, as an example of a protection target, namely, a protected circuit, to be protected by the protection circuit according to the at least one embodiment of the present invention.

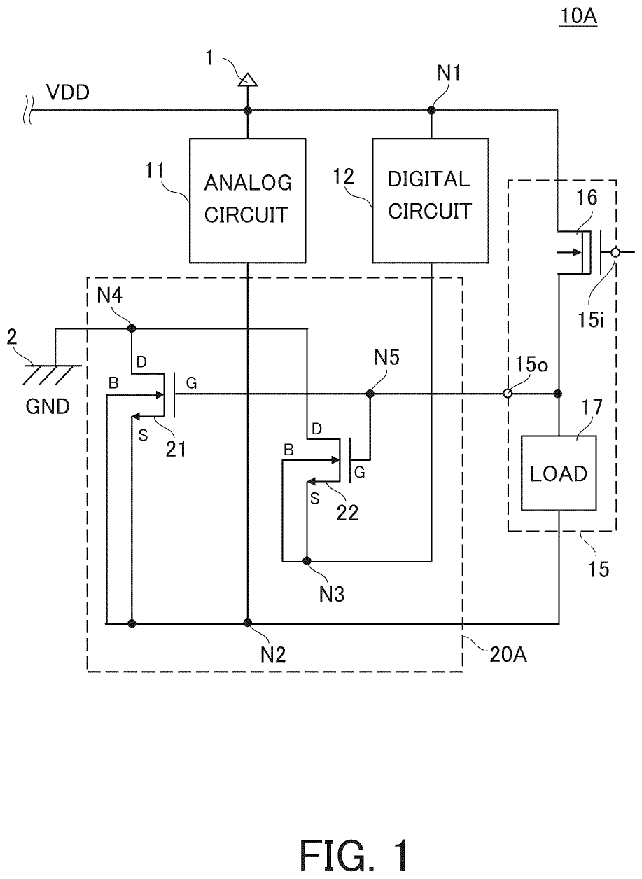

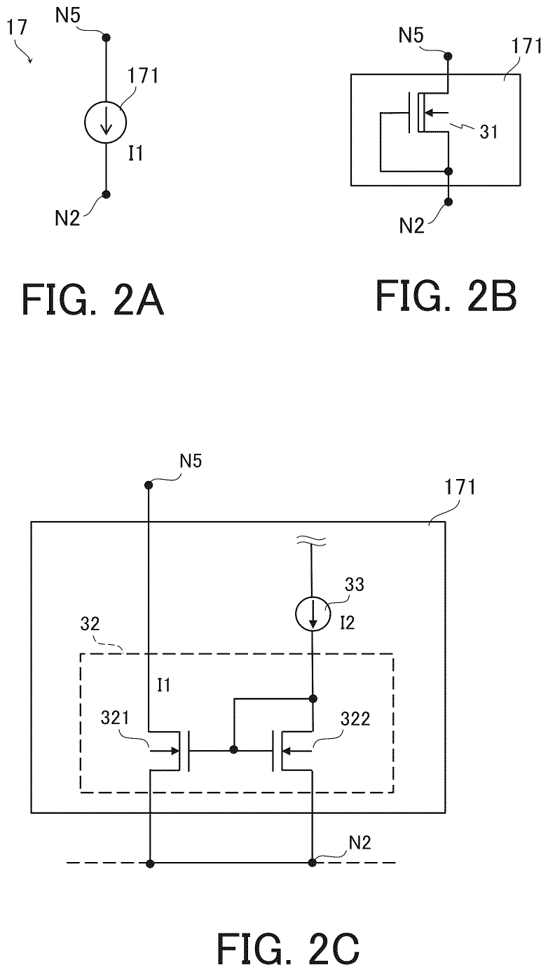

FIG. 1 is a circuit diagram of a semiconductor device 10A including a protection circuit 20A, serving as an example of the semiconductor device including the protection circuit according to the at least one embodiment of the present invention. FIG. 2A is a circuit diagram for illustrating a current source 171 serving as a first configuration example of a load 17. FIG. 2B and FIG. 2C are circuit diagrams for illustrating a first configuration example and a second configuration example, respectively, of the current source 171.

The protection circuit 20A and the semiconductor device 10A are described with reference to FIG. 1. The semiconductor device 10A includes an analog circuit 11, a digital circuit 12, the protection circuit 20A, and a step-down circuit 15. The analog circuit 11, the digital circuit 12, the protection circuit 20A, and the step-down circuit 15 form a semiconductor integrated circuit formed on a semiconductor substrate.

Here, the digital circuit 12 serving as a first circuit handles discrete signals and also controls a switching power supply or a charge pump allowing a large current to flow in accordance with a switching operation. For that reason, a fluctuation and a maximum value of the current during operation are generally larger in the digital circuit 12 than in the analog circuit 11. In view of this, in the description of the at least one embodiment, the digital circuit 12 is assumed to include a noise source.

The analog circuit 11 serving as a second circuit is connected in parallel to the digital circuit 12, and may be affected by noise. The analog circuit 11 provided with no noise countermeasure is affected by noise generated by the noise source, but, as described later, can operate stably in the semiconductor device 10A configured to be capable of suppressing an influence of noise generated by the noise source. Further, the analog circuit 11 and the digital circuit 12 are protection targets to be protected by the protection circuit 20A from the application of a reverse-polarity power supply voltage, namely, the protected circuits of the protection circuit 20A.

The analog circuit 11, the digital circuit 12, and the step-down circuit 15 each include a first end connected to a VDD terminal 1 for supplying a voltage VDD serving as an example of the power supply voltage, and a second end connected to a GND terminal 2 for supplying, without intermediation of the protection circuit 20A, a voltage GND serving as another example of the power supply voltage. The second end of each of the analog circuit 11, the digital circuit 12, and the step-down circuit 15 is connected to the protection circuit 20A, and is connected to the GND terminal 2 via the protection circuit 20A. Herein, a connection point of each of the first ends of the analog circuit 11, the digital circuit 12, and the step-down circuit 15 and the VDD terminal 1 serving as a power supply terminal for supplying the voltage VDD is referred to as “node N1.”

The step-down circuit 15 serving as a gate voltage control circuit includes, for example, a depletion-type NMOS transistor 16, the load 17, and an output terminal 15o connected to a connection point of the depletion-type NMOS transistor 16 and the load 17. A second end serving as another end of the load 17 opposite to a first end thereof connected to the depletion-type NMOS transistor 16 and the output terminal 15o is connected to the second end of the analog circuit 11. Herein, a connection point of the load 17 and the analog circuit 11 is referred to as “node N2.” The step-down circuit 15 including the depletion-type NMOS transistor 16 is a so-called source follower further including an input terminal 15i connected to a gate of the depletion-type NMOS transistor 16.

A configuration example of the load 17 is described below with reference to FIG. 2A to FIG. 2C. The load 17 is, for example, the current source 171 for supplying a constant current I1 in a direction from a node N5 toward the node N2, as illustrated in FIG. 2A. For example, the current source 171 may include a depletion-type NMOS transistor 31 having a gate and a source connected to each other, as illustrated in FIG. 2B, or may include a current source 33 for supplying a constant current I2 to a drain of an NMOS transistor 322, and a current mirror circuit 32, as illustrated in FIG. 2C.

The current mirror circuit 32 includes, for example, an NMOS transistor 321, and the NMOS transistor 322 including a gate connected to a gate of the NMOS transistor 321 and the drain of the NMOS transistor 322. The current mirror circuit 32 causes the constant current I1 (=mI2) obtained by copying the constant current I2 at a predetermined mirror ratio “m” (where “m” is any positive number) to flow to a drain of the NMOS transistor 321.

Referring back to FIG. 1, the protection circuit 20A is described. The protection circuit 20A includes an NMOS transistor 21 connecting the analog circuit 11 and the GND terminal 2, and an NMOS transistor 22 connecting the digital circuit 12 and the GND terminal 2. The NMOS transistor 21 is electrically isolated form the digital circuit 12, and the NMOS transistor 22 is electrically isolated from the analog circuit 11.

The NMOS transistor 21 serving as a second protection transistor includes, for example, a drain and a gate, as well as a source and a back gate connected to the node N2. The node N2 is a reference node for the analog circuit 11.

The NMOS transistor 22 serving as a first protection transistor includes, for example, a drain connected to the drain of the NMOS transistor 21, a gate connected to the gate of the NMOS transistor 21, and a source and a back gate connected to a node N3. The node N3 is a reference node for the digital circuit 12.

The drain of the NMOS transistor 21 and the drain of the NMOS transistor 22 are connected to each other. Herein, a connection point of the drain of the NMOS transistor 21 and the drain of the NMOS transistor 22 is referred to as “node N4.” The node N4 is connected to the GND terminal 2 serving as a power supply terminal for supplying the voltage GND. The node N5 serving as a connection point of the gate of the NMOS transistor 21 and the gate of the NMOS transistor 22 is connected to the output terminal 15o of the step-down circuit 15.

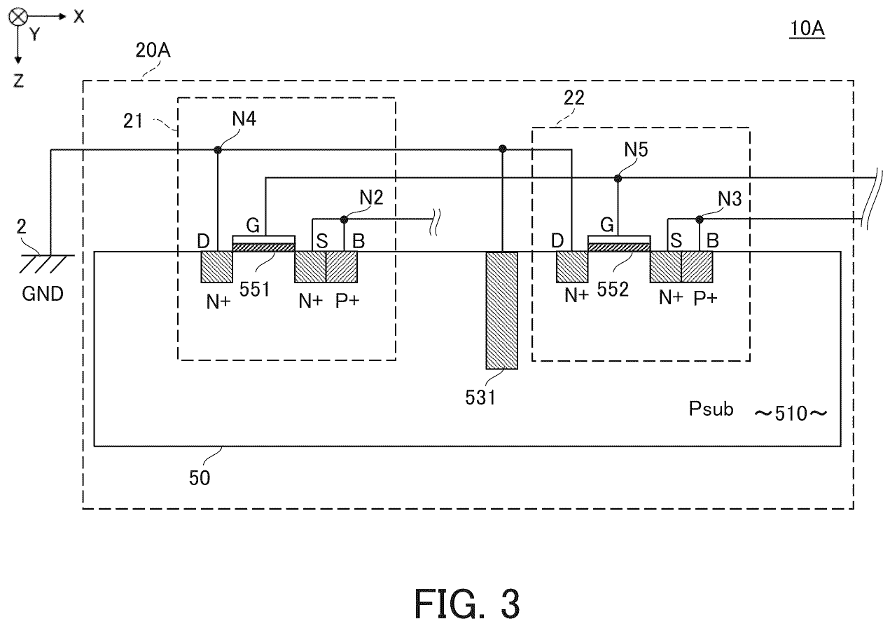

FIG. 3 is a cross-sectional view of the protection circuit 20A. An X axis, a Y axis, and a Z axis illustrated in FIG. 3 are axes of a three-dimensional Cartesian coordinate system. In the at least one embodiment, a length in the X-axis direction is referred to as “width,” a length in the Y-axis direction is referred to as “depth,” a length in the Z-axis direction is referred to as “thickness” or “depth,” and an XY plane (a surface at a depth of 0) is referred to as “surface of semiconductor substrate 50.” Further, the node N2 to the node N5 illustrated in FIG. 3 correspond to the node N2 to the node N5 illustrated in other drawings such as FIG. 1.

The protection circuit 20A is formed on the semiconductor substrate 50 as a semiconductor integrated circuit. For example, the semiconductor substrate 50 in the semiconductor device 10A includes a substrate region (Psub) 510 of a P type serving as a first conductivity type, and a semiconductor region of the P type being the same conductivity type as that of the substrate region 510, a semiconductor region of an N type serving as a second conductivity type being a conductivity type different from that of the substrate region 510, and an isolation wall 531. The semiconductor region of the P type, the semiconductor region of the N type, and the isolation wall 531 are formed in the substrate region 510. The isolation wall 531 is formed of an N-type semiconductor. In the protection circuit 20A and the semiconductor device 10A illustrated as an example in FIG. 3, the isolation wall 531 is connected to the GND terminal 2.

The NMOS transistor 21 and the NMOS transistor 22 are formed in the substrate region 510. A gate G of the NMOS transistor 21 is provided to the semiconductor substrate 50 (more specifically, the substrate region 510) through an insulating layer 551. A gate G of the NMOS transistor 22 is provided to the semiconductor substrate 50 (more specifically, the substrate region 510) through an insulating layer 552. The NMOS transistor 21 and the NMOS transistor 22 are formed so as to sandwich the isolation wall 531 in the X-axis direction serving as a first direction. In other words, the isolation wall 531 is provided between the NMOS transistor 21 and the NMOS transistor 22 in the X-axis direction.

Here, drains D and sources S of the NMOS transistors 21 and 22 are formed with a high impurity concentration (N+) with respect to an N-type region (not shown) within the N-type semiconductor region. Back gates B of the NMOS transistors 21 and 22 are formed with a high impurity concentration (P+) with respect to the substrate region 510. The drain D of the NMOS transistor 21 and the drain D of the NMOS transistor 22, namely, the node N4, are connected to the GND terminal 2.

Next, an operation of the protection circuit 20A and the semiconductor device 10A is described. The description of the operation of the protection circuit 20A and the semiconductor device 10A is premised on the assumption that the analog circuit 11 and the digital circuit 12 are circuits allowing a reverse current to flow through a parasitic diode, in a state of not being connected to the protection circuit 20A and in a state in which a negative voltage is applied to the VDD terminal 1, that is, in a state in which a power supply voltage having a reverse polarity to that in a steady state in which a positive voltage is applied to the VDD terminal 1 is applied.

First, in a state in which a positive voltage is applied to the VDD terminal 1, that is, in the steady state, a current flowing inside the analog circuit 11 flows in a direction from the node N1 toward the node N2, and a current flowing inside the digital circuit 12 flows in a direction from the node N1 toward the node N3. The step-down circuit 15 supplies a gate voltage Vg of the NMOS transistor 22, serving as a first control voltage, and a gate voltage Vg of the NMOS transistor 21, serving as a second control voltage, to the gates of the NMOS transistors 22 and 21, respectively.

In controlling the NMOS transistor 21 and the NMOS transistor 22 by the step-down circuit 15 using a source follower illustrated as an example in FIG. 1, a bias voltage Vbias serving as a gate voltage of the depletion-type NMOS transistor 16 being a step-down transistor, that is, a voltage to be supplied to the input terminal 15i, may be appropriately set such that the voltage of the node N5, serving as each gate voltage Vg, is higher than a threshold voltage Vth1 of the NMOS transistor 21 and a threshold voltage Vth2 of the NMOS transistor 22.

In a case in which the NMOS transistor 21 and the NMOS transistor 22 are in an on state to allow currents to flow in the direction from the respective sources (the node N2 and the node N3) toward the drains (the node N4), the bias voltage Vbias is set such that the gate voltages Vg satisfy relationships indicated by Expression (1) and Expression (2), respectively, through use of the bias voltage Vbias, a gate-source voltage Vgs of the depletion-type NMOS transistor 16, and a threshold voltage Vth sf of the depletion-type NMOS transistor 16.

$$Vg = Vbias - Vgs \approx Vbias - Vth\_sf > Vth 1 \qquad ( 1 )$$

$$Vg = Vbias - Vgs \approx Vbias - Vth\_sf > Vth 2 \qquad ( 2 )$$

The threshold voltage Vth sf is negative with a depletion-type transistor adopted as the step-down transistor, thereby enabling each gate voltage Vg to be equal to or higher than the bias voltage Vbias (Vg≥Vbias). That is, the NMOS transistor 21 and the NMOS transistor 22 can be easily turned on by adopting a depletion-type transistor, such as the depletion-type NMOS transistor 16, as the step-down transistor.

For the stable operation of the analog circuit 11 and the digital circuit 12, it is desired to operate the node N2 and the node N3 at a voltage close to the voltage GND. In this case, the NMOS transistor 21 and the NMOS transistor 22 serving as the protection transistors operate in a resistance region in which the drain-source voltage is close to 0 V. Thus, a current flowing from the VDD terminal 1 to the node N2 flows to the GND terminal 2 through an on-resistance of the NMOS transistor 21. A current flowing from the VDD terminal 1 to the node N3 flows to the GND terminal 2 through an on-resistance of the NMOS transistor 22.

In a case in which the NMOS transistor 21 and the NMOS transistor 22 operate in the resistance region in which the drain-source voltage is close to 0 V, a voltage Vint_gnd1_ope of the node N2 can be expressed by Expression (3) through use of a resistance value Ron21 of the on-resistance of the NMOS transistor 21 and a current value Iope_gnd1 of a current flowing from the node N2 toward the node N4. Further, a voltage Vint_gnd2_ope of the node N3 can be expressed by Expression (4) through use of a resistance value Ron22 of the on-resistance of the NMOS transistor 22 and a current value Iope_gnd2 of a current flowing from the node N3 toward the node N4.

$$Vint\_gnd1 \_ope = R o n 21 \times Iope\_gnd1 \qquad ( 3 )$$

$$Vint\_gnd2 \_ope = Ron 22 \times Iope\_gnd2 \qquad ( 4 )$$

Next, in the state in which a negative voltage is applied to the VDD terminal 1, that is, in a case in which the reverse-polarity power supply voltage is applied thereto, a reverse current flows from the node N2 toward the node N1 through the parasitic diode in the analog circuit 11. In the digital circuit 12, a reverse current flows from the node N3 toward the node N1 through the parasitic diode. At this time, the gate voltages Vg of the NMOS transistors 21 and 22, the voltage Vint_gnd1_ope of the node N2, and the voltage Vint_gnd2_ope of the node N3 decrease following the voltage of the VDD terminal 1. As a result, a gate-source voltage of the NMOS transistor 21 falls below the threshold voltage Vth1, thereby bringing the NMOS transistor 21 into an off state. Further, a gate-source voltage of the NMOS transistor 22 falls below the threshold voltage Vth2, thereby bringing the NMOS transistor 22 into an off state.

In the protection circuit 20A, a current from the digital circuit 12 flows into the NMOS transistor 22 through the node N3. Most of the current that has flowed into the NMOS transistor 22 flows to the GND terminal 2 through the NMOS transistor 22. Meanwhile, because the NMOS transistor 22 and the NMOS transistor 21 share the substrate region 510 by having the drains D, the sources S, and the back gates B formed therein, carriers move between the NMOS transistor 22 and the NMOS transistor 21 through the substrate region 510.

In the protection circuit 20A, the isolation wall 531 is provided between the NMOS transistor 21 and the NMOS transistor 22 in the X-axis direction serving as the first direction as illustrated in FIG. 3. Thus, the isolation wall 531 serves as a physical barrier for carriers that cause noise. In addition, a voltage is applied to the isolation wall 531. Thus, for electrons serving as an example of the carriers, the isolation wall 531 serves not only as a physical barrier but also as an electrical barrier. Accordingly, the protection circuit 20A can reduce, with the isolation wall 531, an amount of noise propagating from the substrate region 510 to the drain D, the source S, and the back gate B being the electrodes of the NMOS transistor 21.

As described above, with the protection circuit 20A and the semiconductor device 10A, the analog circuit 11 and the digital circuit 12 can be protected from the application of the reverse-polarity power supply voltage because the protection circuit 20A includes the NMOS transistors 21 and 22. Further, the propagation of noise generated in the digital circuit 12 to other circuits, such as the analog circuit 11, can be reduced because the protection circuit 20A includes the isolation wall 531.

Further, with the protection circuit 20A and the semiconductor device 10A, as can be understood from Expressions (3) and (4), a voltage drop from the node N2 to the node N4 and a voltage drop from the node N3 to the node N4 can be individually adjusted by adjusting the resistance values of the on-resistances of the NMOS transistors 21 and 22 to appropriate values. That is, with the protection circuit 20A and the semiconductor device 10A, a degree of freedom of circuit design in the protection circuit 20A and the semiconductor device 10A can be increased. The adjustment of the resistance values of the on-resistances of the NMOS transistors 21 and 22 may be appropriately selected from a few methods, for example, changing aspect ratios of the NMOS transistors 21 and 22.

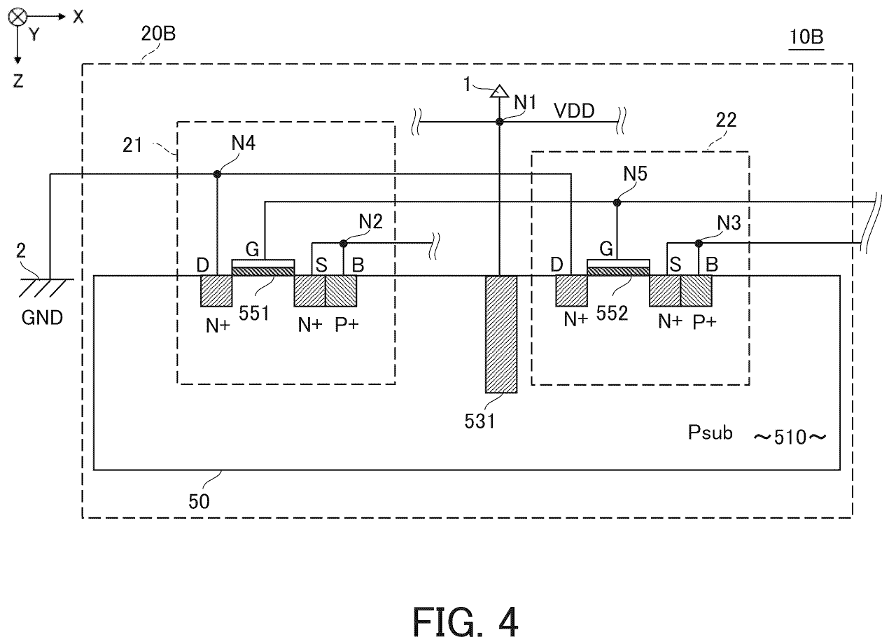

The present invention is not limited to the at least one embodiment described above as it is, and can be implemented in various forms other than the at least one embodiment described above during the course of implementation. Various omissions, additions, substitutions, or modifications can be made without departing from the gist of the invention. That is, the protection circuit and the semiconductor device according to the present invention may be modified as illustrated as examples in FIG. 4 to FIG. 9 described later. Modification examples are described below.

FIG. 4 is a cross-sectional view of a protection circuit 20B. An X axis, a Y axis, a Z axis, and the node N2 to the node N5 illustrated in FIG. 4 are the same as those of FIG. 3.

A semiconductor device 10B differs from the semiconductor device 10A in that the semiconductor device 10B includes the protection circuit 20B instead of the protection circuit 20A, and is otherwise substantially the same as the semiconductor device 10A. Further, the protection circuit 20B differs from the protection circuit 20A in that a connection destination of the isolation wall 531 is different, and is otherwise substantially the same as the semiconductor device 10A. In view of this, in the description of the protection circuit 20B and the semiconductor device 10B, the isolation wall 531, differing from that of the protection circuit 20A and the semiconductor device 10A, is mainly described.

In the protection circuit 20B in the semiconductor device 10B illustrated as an example in FIG. 4, the isolation wall 531 is connected to the VDD terminal 1 (the node N1). Similarly to the GND terminal 2 (the node N4) serving as the connection destination of the isolation wall 531 illustrated as an example in FIG. 3, the VDD terminal 1 is an example of a node (hereinafter referred to as “non-negative voltage supply node”) for supplying a voltage (hereinafter referred to as “non-negative voltage”) equal to or higher than the voltage of the substrate region 510. That is, the isolation wall in the protection circuit and the semiconductor device including the protection circuit according to the at least one embodiment may be connected to any non-negative voltage supply node such as the VDD terminal 1 or the output terminal 15o as illustrated in FIG. 1, other than to the GND terminal 2 (the node N4). The non-negative voltage may be a voltage obtained by step-down of the voltage VDD. In a case in which the protection circuit or the semiconductor device is receiving a voltage supply from a power supply for supplying a voltage higher than that of the substrate region 510, that is, a positive voltage, independently of the VDD terminal 1, the non-negative voltage may be a voltage supplied from the power supply.

With the protection circuit 20B and the semiconductor device 10B configured in this manner, the analog circuit 11 and the digital circuit 12 can be protected from the application of the reverse-polarity power supply voltage, similarly to the protection circuit 20A and the semiconductor device 10A, because the protection circuit 20B includes the NMOS transistors 21 and 22. Further, the propagation of noise generated in the digital circuit 12 to other circuits, such as the analog circuit 11, can be reduced, similarly to the protection circuit 20A and the semiconductor device 10A, because the protection circuit 20B includes the isolation wall 531 to which a positive voltage is applied.

In the protection circuit and the semiconductor device including the protection circuit according to the at least one embodiment, the isolation wall 531 may be in a state of not being connected to any one of the terminals or the nodes, that is, may be in a floating state.

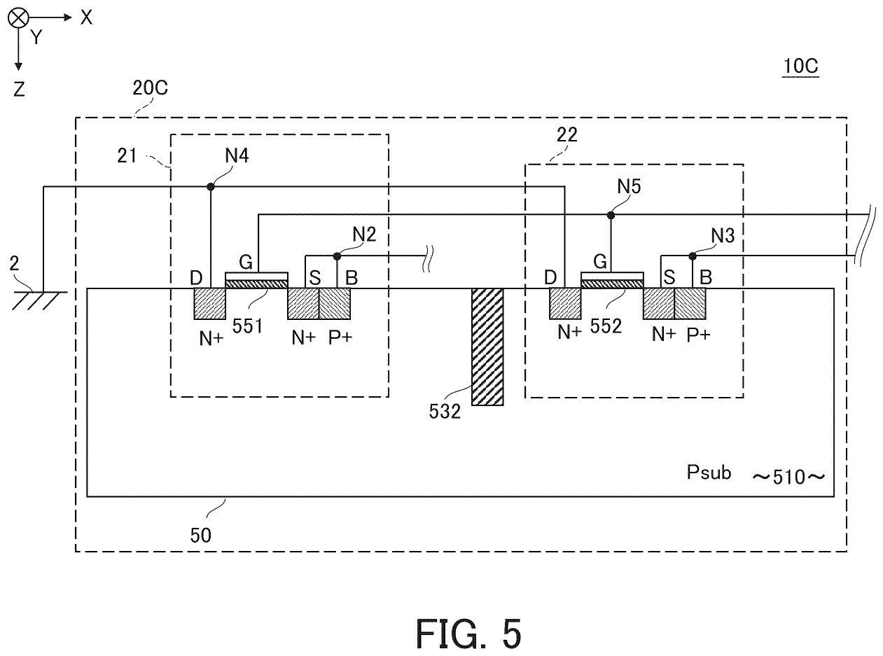

FIG. 5 is a cross-sectional view of a protection circuit 20C. An X axis, a Y axis, a Z axis, and the node N2 to the node N5 illustrated in FIG. 5 are the same as those of FIG. 3 and FIG. 4.

A semiconductor device 10C differs from the semiconductor device 10A in that the semiconductor device 10C includes the protection circuit 20C instead of the protection circuit 20A, and is otherwise substantially the same as the semiconductor device 10A. Further, the protection circuit 20C differs from the protection circuit 20A in that the protection circuit 20C includes an isolation wall 532 instead of the isolation wall 531, and is otherwise substantially the same as the semiconductor device 10A. In view of this, in the description of the protection circuit 20C and the semiconductor device 10C, the isolation wall 532, differing from the isolation wall 531 of the protection circuit 20A and the semiconductor device 10A, is mainly described.

In the protection circuit 20C and the semiconductor device 10C illustrated as an example in FIG. 5, the isolation wall 532 is formed of, for example, an insulator. The isolation wall 532 is provided in the substrate region 510, and more specifically, between the NMOS transistor 21 and the NMOS transistor 22 in the X-axis direction, similarly to the isolation wall 531. Further, the isolation wall 532 is in a state of not being connected to any terminal, that is, in a floating state. The isolation wall 532 formed of the insulator does not function as an electrical barrier for carriers that cause noise. However, the isolation wall 532 functions as a physical barrier, similarly to the isolation wall 531 formed of the N-type semiconductor. Accordingly, the protection circuit 20C can reduce, with the isolation wall 532, the amount of noise propagating from the substrate region 510 to the drain D, the source S, and the back gate B being the electrodes of the NMOS transistor 21, although to a lesser extent than in the cases of the protection circuits 20A and 20B.

With the protection circuit 20C and the semiconductor device 10C configured in this manner, the analog circuit 11 and the digital circuit 12 can be protected from the application of the reverse-polarity power supply voltage, similarly to the protection circuit 20A and the semiconductor device 10A, because the protection circuit 20C includes the NMOS transistors 21 and 22. Further, the propagation of noise generated in the digital circuit 12 to other circuits, such as the analog circuit 11, can be reduced because the protection circuit 20C includes the isolation wall 532.

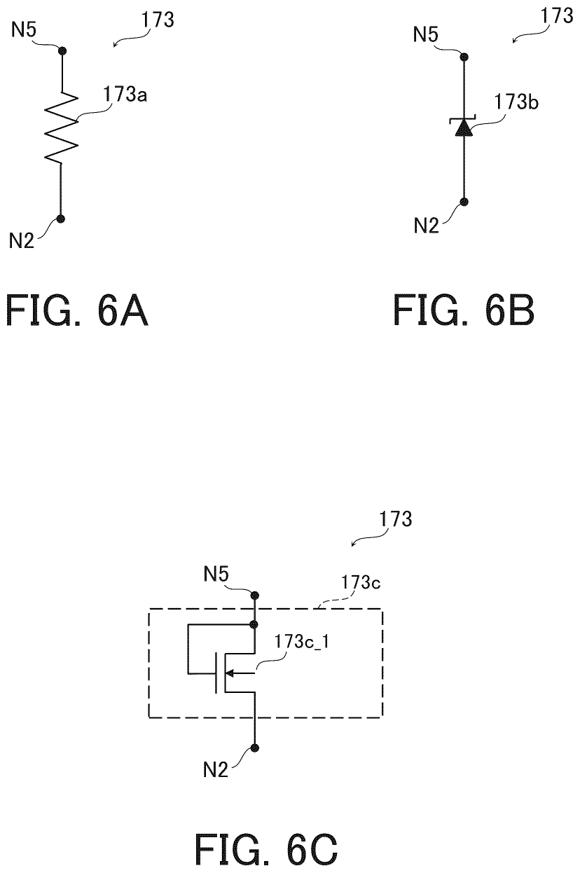

The step-down circuit 15 described above is an example including the current source 171 exemplifying the load 17, but may include, instead of the current source 171, an I/V conversion circuit 173 for converting current into voltage as illustrated in FIG. 6A to FIG. 6C.

FIG. 6A to FIG. 6C are circuit diagrams for illustrating a second configuration example to a fourth configuration example, respectively, of the load 17.

In the at least one embodiment described above, as an example of the I/V conversion circuit 173, the load 17 may adopt a resistor element 173a as illustrated in FIG. 6A (the second configuration example), may adopt a Zener diode 173b as illustrated in FIG. 6B (the third configuration example), or may adopt a transistor circuit 173c including at least one diode-connected MOS transistor 173c_1 as illustrated in FIG. 6C (the fourth configuration example). The transistor circuit 173c is not limited to the case of including one diode-connected MOS transistor 173c_1, and may be configured by connecting in series a plurality of diode-connected MOS transistors including the MOS transistor 173c_1.

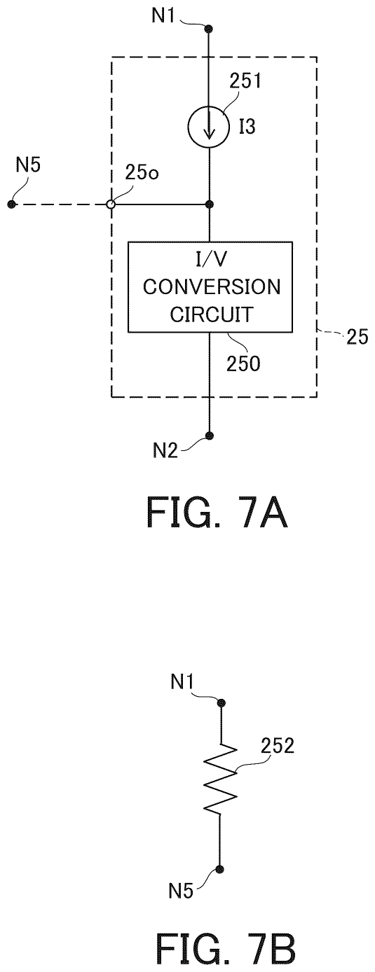

The semiconductor devices 10A and 10B described above each include the step-down circuit 15. However, the semiconductor devices 10A and 10B may include a step-down circuit 25 as illustrated in FIG. 7A and FIG. 7B instead of the step-down circuit 15.

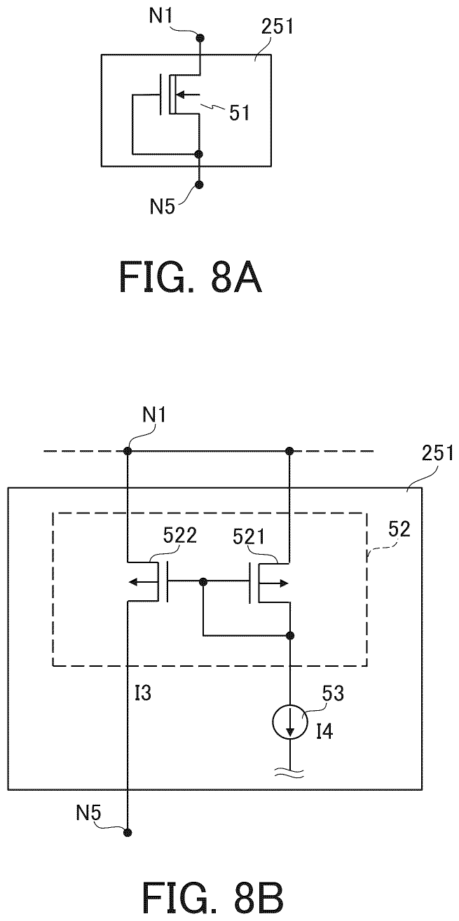

FIG. 7A is a circuit diagram of the step-down circuit 25 including a current source 251. FIG. 7B is a partial circuit diagram of the step-down circuit 25 including a resistor element 252 instead of the current source 251. FIG. 8A is a circuit diagram for illustrating a first configuration example of the current source 251. FIG. 8B is a circuit diagram for illustrating a second configuration example of the current source 251.

In the at least one embodiment described above, in contrast to the step-down circuit 15, as illustrated as an example in FIG. 7A, the step-down circuit 25 includes the current source 251 instead of the depletion-type NMOS transistor 16, includes an I/V conversion circuit 250 instead of the load 17, and further includes an output terminal 250 corresponding to the output terminal 15o. As partially illustrated as an example in FIG. 7B, the step-down circuit 25 may include the resistor element 252 instead of the current source 251.

The current source 251 may include, for example, a depletion-type NMOS transistor 51 having a gate and a source connected to each other, as illustrated in FIG. 8A, or may include a current source 53 for supplying a constant current I4 to a drain of a PMOS transistor 522, and a current mirror circuit 52, as illustrated in FIG. 8B.

The current mirror circuit 52 includes, for example, a PMOS transistor 521 including a gate connected to a drain of the PMOS transistor 521, and the PMOS transistor 522 including a gate connected to the gate and the drain of the PMOS transistor 521. The current mirror circuit 52 causes a constant current I3 (=kI4) obtained by copying the constant current I4 at a predetermined mirror ratio “k” (where “k” is any positive number) to flow to the drain of the PMOS transistor 521.

Similarly to the I/V conversion circuit 173 described above, the I/V conversion circuit 250 may adopt a resistor element, a Zener diode, a transistor circuit including at least one diode-connected MOS transistor, or a transistor circuit configured by connecting a plurality of diode-connected MOS transistors in series.

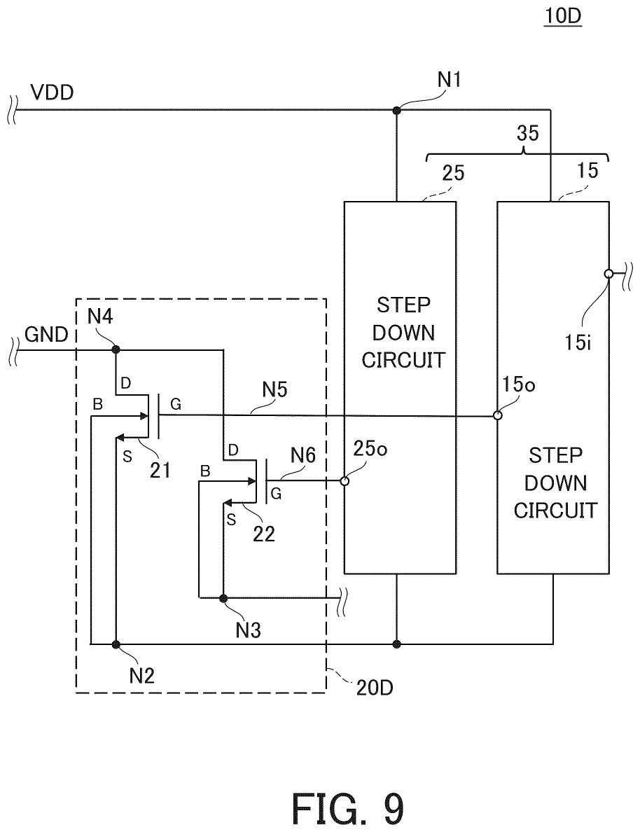

The protection circuits 20A, 20B, and 20C described above are examples of a protection circuit lacking the step-down circuit 15 or the step-down circuit 25. However, the protection circuits 20A, 20B, and 20C are not limited to those examples. The protection circuits 20A, 20B, and 20C and a protection circuit 20D described later with reference to FIG. 9 may further include a pair of the step-down circuits 15 and 25 or a step-down circuit 35 described later with reference to FIG. 9.

The protection circuits 20A, 20B, and 20C described above are examples in which the NMOS transistor 21 and the NMOS transistor 22 include gates in common, but the gate of the NMOS transistor 21 and the gate of the NMOS transistor 22 are not required to be common. That is, the gate of the NMOS transistor 21 and the gate of the NMOS transistor 22 may be independent of each other. In a case in which the gates of the NMOS transistor 21 and the NMOS transistor 22 are independent of each other, the step-down circuit may be formed by combining the step-down circuit 15 and the step-down circuit 25 such that independent gate voltages can be supplied.

FIG. 9 is a partial circuit diagram of the protection circuit 20D and a semiconductor device 10D serving as an example of the protection circuit and the semiconductor device including the protection circuit according to the at least one embodiment. In FIG. 9, the analog circuit 11 and the digital circuit 12 connected to each other in the same way as in FIG. 1 are not shown from the viewpoint of clarity and simplicity.

The semiconductor device 10D differs from the semiconductor device 10A in that the semiconductor device 10D includes the protection circuit 20D instead of the protection circuit 20A and that the semiconductor device 10D includes the step-down circuit 35 instead of the step-down circuit 15, and is otherwise substantially the same as the semiconductor device 10A. The protection circuit 20D differs from the protection circuit 20A in that the gate of the NMOS transistor 21 and the gate of the NMOS transistor 22 form the node N5 and the node N6 different from (independent of) each other, respectively, and is otherwise substantially the same as the semiconductor device 10A. The step-down circuit 35 serving as the gate voltage control circuit is a step-down circuit capable of supplying two independent voltages, and as illustrated as an example in FIG. 9, includes one step-down circuit 15 and one step-down circuit 25.

The step-down circuit 35 illustrated in FIG. 9 is an example in which the step-down circuit 25 for supplying a voltage to the gate of the NMOS transistor 22 is connected between the node N1 and the node N2. However, the present invention is not limited thereto. The step-down circuit 25 for supplying a voltage to the gate of the NMOS transistor 22 may be connected to the node N3 instead of to the node N2. Further, the step-down circuit 35 illustrated in FIG. 9 is an example of including one step-down circuit 15 and one step-down circuit 25. However, the present invention is not limited thereto. The step-down circuit 35 may include a plurality of step-down circuits 15, for example, two step-down circuits 15, or may include a plurality of step-down circuits 25, for example, two step-down circuits 25.

The isolation wall 531 illustrated as an example in FIG. 3 and FIG. 4 and the isolation wall 532 illustrated as an example in FIG. 5 are examples in which one isolation wall is arranged in the X-axis direction indicated in FIG. 3, FIG. 4, and FIG. 5, that is, the width direction of the semiconductor substrate 50. However, a plurality of isolation walls may be arranged at a predetermined distance in the same direction. Further, a depth, or a length in the Z-axis direction indicated in FIG. 3, FIG. 4, and FIG. 5, of the isolation wall 531 or the isolation wall 532 can exert some effect as long as the depth is finite. However, the depth is preferred to be equal to or greater than the depths of the drain D, the source S, and the back gate B being the electrodes of the NMOS transistor 21 and the NMOS transistor 22.

The protection circuits 20A to 20D and the semiconductor devices 10A to 10D described above have been described by taking, as an example, the case in which the first conductivity type and the second conductivity type are the P type and the N type, respectively, and VDD is a positive voltage in the steady state. However, the protection circuit and the semiconductor device according to the at least one embodiment may be obtained by reversing the conductivity types (the P type and the N type) of the semiconductor substrate 50, the polarity of polar elements such as the NMOS transistors 21 and 22, and the polarity (positive and negative) of the power supply voltage.

The at least one embodiment and modifications thereof described above are encompassed in the scope and the gist of the invention, and are encompassed in the invention defined in the appended claims and equivalents thereof.

What is claimed is:

1. A protection circuit formed on a semiconductor substrate including a substrate region of a first conductivity type, a region of the first conductivity type formed in the substrate region, and a region of a second conductivity type formed in the substrate region, the protection circuit being configured to protect a protected circuit from application of a power supply voltage having a reverse polarity to a polarity of a power supply voltage applied in a steady state,
the protected circuit including:
a first circuit located between a first power supply terminal and a second power supply terminal and connected to the second power supply terminal via the protection circuit, the first circuit including a noise source; and
a second circuit located between the first power supply terminal and the second power supply terminal and connected in parallel to the first circuit via the protection circuit,
the protection circuit comprising:
a first protection transistor including a drain connected to the second power supply terminal, a gate configured to receive supply of a first control voltage, and a source and a back gate connected to the first circuit;
a second protection transistor including a drain connected to the drain of the first protection transistor, a gate configured to receive supply of a second control voltage, and a source and a back gate which are electrically isolated from a connection point of the source and the back gate of the first protection transistor and the first circuit and connected to the second circuit, the drain, the gate, the source, and the back gate of the second protection transistor positioning side by side in a first direction along a surface of the semiconductor substrate in which the drain, the gate, the source, and the back gate of the first protection transistor arrange side by side; and
an isolation wall provided between the first protection transistor and the second protection transistor in the first direction, the isolation wall being floating.

2. The protection circuit according to claim 1, wherein the isolation wall comprises a region of the second conductivity type.

3. The protection circuit according to claim 1, wherein the isolation wall comprises an insulator.

4. A protection circuit formed on a semiconductor substrate including a substrate region of a first conductivity type, a region of the first conductivity type formed in the substrate region, and a region of a second conductivity type formed in the substrate region, the protection circuit being configured to protect a protected circuit from application of a power supply voltage having a reverse polarity to a polarity of a power supply voltage applied in a steady state,
the protected circuit including:
a first circuit located between a first power supply terminal and a second power supply terminal and connected to the second power supply terminal via the protection circuit, the first circuit including a noise source; and
a second circuit located between the first power supply terminal and the second power supply terminal and connected in parallel to the first circuit via the protection circuit,
the protection circuit comprising:
a first protection transistor including a drain connected to the second power supply terminal, a gate configured to receive supply of a first control voltage, and a source and a back gate connected to the first circuit;
a second protection transistor including a drain connected to the drain of the first protection transistor, a gate configured to receive supply of a second control voltage, and a source and a back gate which are electrically isolated form a connection point of the source and the back gate of the first protection transistor and the first circuit and connected to the second circuit, the drain, the gate, the source, and the back gate of the second protection transistor positioning side by side in a first direction along a surface of the semiconductor substrate in which the drain, the gate, the source, and the back gate of the first protection transistor arrange side by side; and
an isolation wall of the second conductivity type which is provided between the first protection transistor and the second protection transistor in the first direction, and to which a voltage equal to or higher than a voltage of the substrate region is to be applied.

5. The protection circuit according to claim 1, wherein the isolation wall has a depth in a thickness direction of the semiconductor substrate, the depth being equal to or greater than depths of the drain, the gate, the source, and the back gate of the first protection transistor.

6. A semiconductor device, comprising a semiconductor integrated circuit formed on a semiconductor substrate including a substrate region of a first conductivity type, a region of the first conductivity type formed in the substrate region, and a region of a second conductivity type formed in the substrate region,
the semiconductor integrated circuit including the protection circuit of claim 1,
the protected circuit including a first circuit located between a first power supply terminal and a second power supply terminal and connected to the second power supply terminal via the protection circuit, the first circuit including a noise source, and a second circuit located between the first power supply terminal and the second power supply terminal and connected in parallel to the first circuit via the protection circuit.

7. The semiconductor device according to claim 6, wherein the isolation wall has a depth in a thickness direction of the semiconductor substrate, the depth being equal to or greater than depths of the drain, the gate, the source, and the back gate of the first protection transistor.

8. The semiconductor device according to claim 6, wherein the semiconductor integrated circuit includes the protected circuit.

9. The semiconductor device according to claim 7, wherein the semiconductor integrated circuit includes the protected circuit.
